(19) United States
(12) Patent Application Publication
(10) Pub. No.: US 2007/0040589 A1
(43) Pub. Date: Feb. 22, 2007

(54) Signal generating circuit

(75) Inventor: Kenjiro Matoba, Miyazaki (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/492,047

(22) Filed: Jul. 25, 2006

(30) Foreign Application Priority Data
Aug. 16, 2005 (JP) 2005-236058

(51) Int. Cl. H03B 21/00

(52) U.S. Cl. 327/105

(57) ABSTRACT

A signal generating circuit that enables to set an initial oscillation signal level to zero is provided. The circuit includes an adder 11, a first multiplier 12 with an multiplication coefficient of A1, a second multiplier 13 with an multiplication coefficient of A2, a first and second delay element 14, 15 and an initializing circuit 16. Output signal from an output terminal of the circuit is supplied to the first delay element 14, the output of it is supplied to the second delay element and the first multiplier 12. The output signal of the second delay element 15 is supplied to the second multiplier 13, the output signal of the first and second multiplier are supplied to the adder 11. The output of it is supplied to the output terminal. The initializing circuit outputs an initial value y1 and y2 of the first and second delay element such that it satisfies an equation y1*A1+y2*A2=0.

### BACKGROUND OF THE INVENTION

1. Field of the Invention

The present invention relates to a signal generating circuit, in particular, to a signal generation circuit generating digital sign wave having an arbitrary frequency.

2. Description of the Background Art

The conventional signal generator generates a signal from a signal oscillator comprising a plurality of analogue element such as operational amplifiers, resistors, capacitors, etc.. When configuring an oscillation circuit with such analogue components, oscillation frequency and amplitude errors are produced by such analogue element. In addition, circuit element such as capacitor occupies large layout space, so it was difficult to downsizing the circuit dimension.

To avoid such problems, a method that reads a waveform data at each sampling point of waveform from a memory such as ROM and repeating the process to generates a digital sign wave, was proposed. But the method has a drawback that it needs a large capacity ROM to store a number of waveforms according to an increased number of waveforms with different frequencies. To avoid this problem, a signal generating circuit with digital circuit components has been considered.

FIG. 2 shows an example of typical 2^{nd} order recursive filter. The circuit comprises an adder 21, a multiplier 22 with multiplication coefficient A1, a multiplier 23 with multiplication coefficient A2 and delay element 24, 25. When the input of the circuit is X(z) and the output is Y(z), then the transfer function of the circuit is expressed as follows.
Y(z)=X(z)*z²/(z²−A1*z−A2)
Therefore, the condition of oscillation, that is, the condition of output value Y(z) for holding a finite value even if the input X(z)=0, is expressed as follows.
z²−A1*z−A2=0

If we set the coefficient A1 of multiplier 22 to be 2 cos δ and the coefficient A2 of the multiplier 23 to be −1, then the resolution of the 2^{nd} order equation is expressed as follows.
z=e^{±jδ}
If we only consider plus sign solution, the solution of the 2^{nd} equation means that the circuit shown in FIG. 2 oscillates by δ=2πfT, that is the oscillation frequency is f=δ/(2πT), where T is a time period.

An example of such a circuit is, described in the following patent document (Japanese Patent Publication Number H04-302511).

### SUMMARY OF THE INVENTION

Problems to be Solved:

FIG. 3 shows an equivalent circuit of FIG. 2 which replaces the delay element 24, 25 to D type Flip Flop (D-FF) respectively. In the case where each D-FF is reset when the power is turned on, output signal y continues to hold zero level, since the output signal y becomes zero at the oscillation start time(t=0) and we cannot get an oscillation signal.

To solve above mentioned problem an initial value setting circuit is proposed to attach to the delay element 34 (not shown) and the initial value y1 of the D-FF 34 is given by the initial value setting circuit. In this case, the D-FF 34 is initialized to y1 and the D-FF 35 is reset (initial value is set to zero) when the power is turned on and the oscillation value at the time t=0 is given by y1*A1=2*y1*cos δ. This means that initial oscillation value is fluctuated by an oscillation frequency. Therefore, when the initial oscillation value is large, there might occur a problem that a pop noise is generated by a speaker in an application where the speaker is driven by the oscillation signal.

It is therefore an object of the invention to propose a signal generation circuit that can set an initial oscillation value to be zero.

To accomplish above mentioned object, a signal generation circuit of the invention includes an adder, a first multiplier with a multiplication coefficient A1, a second multiplier with a multiplication coefficient A2, and a first and second delay element; the output signal from an output terminal is supplied to an input of the first delay element; the output signal of the first delay element is supplied to an input of the second delay element and to an input of the first multiplier; the output signal of the second delay element is supplied to an input of the second multiplier; the output signal of the first and second multiplier is supplied to an input of the adder; and the output signal of the adder is supplied to an output terminal of the signal generating circuit. The characteristics of the invention is that it includes an initializing circuit which sets up an initial value of the first and second delay element to y1 and y2 respectively such that the equation y1*A1+y2*A2=0 is satisfied (where y1 and y2 is not equal to zero), when the power is applied.

As mentioned above, the signal generation circuit of the invention includes the initializing circuit, the output signal y1, y2 of it is supplied to the first and second delay element for setting to the initial value at power on stage. Therefore, as the initial value y1 and y2 is selected so as to satisfy the equation y1*A1+y2*A2 =0, so the initial oscillation level of the signal generator certainly starts on zero level, and the pop noise never occurs.

### BRIEF DESCRIPTION OF THE DRAWINGS

FIG. 1 shows a configuration diagram of the signal generation circuit in accordance with the embodiment the invention;

FIG. 2 shows a exemplary diagram describing the principal of the oscillation circuit; and

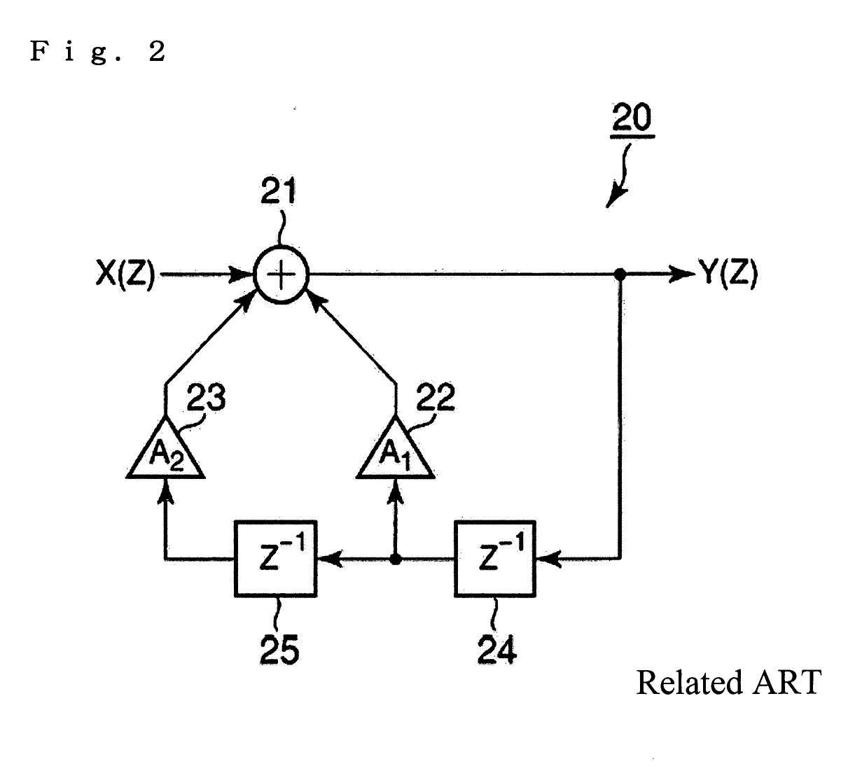

FIG. 3 shows a configuration diagram of a conventional signal generating circuit.

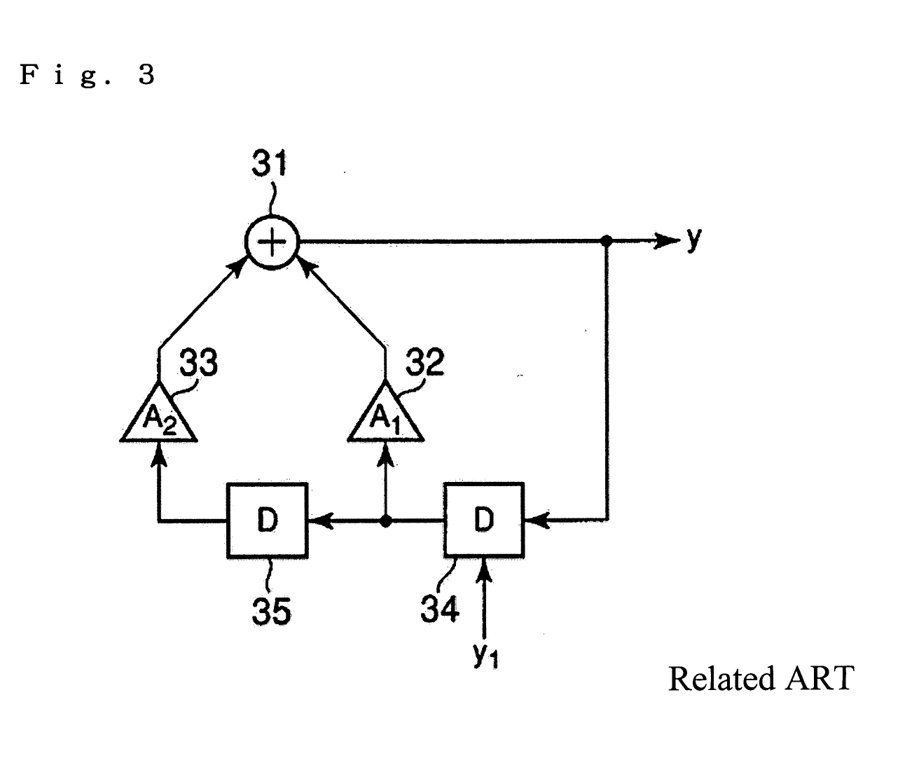

### DETAILED DESCRIPTION OF THE PREFERRED EMBODIMENT

The embodiment of the invention will be explained using drawings below. The drawings are made briefly for only assisting the understanding of the present invention.

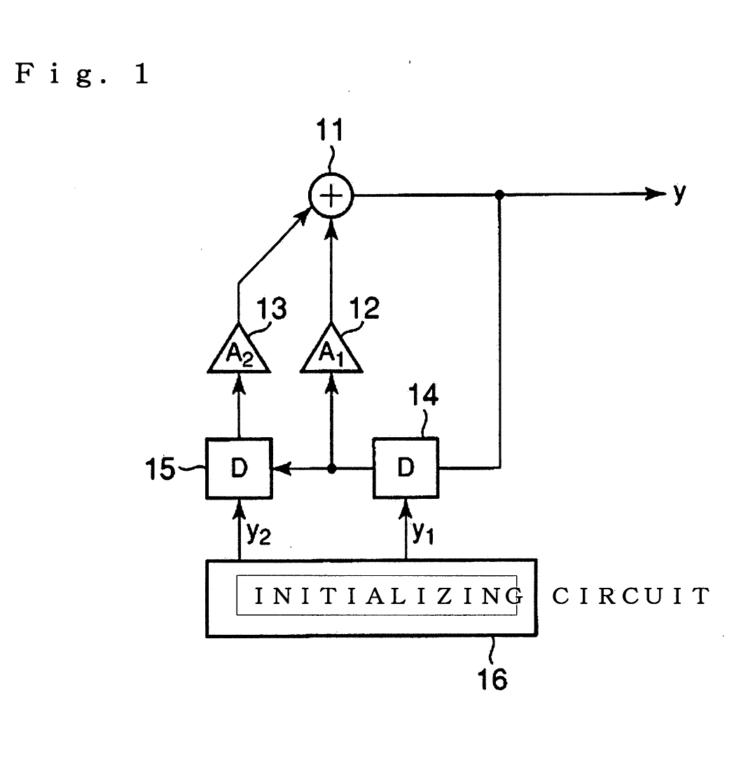

FIG. 1 shows a configuration diagram of the signal generation circuit in accordance with the embodiment the invention. The circuit includes an adder 11, a first multiplier 12 having multiplication coefficient A1, a second multiplier 13 having multiplication coefficient A2, D-FF 14, 15 as a first and second delay element and an initializing circuit 16.

The output signal of an output terminal y is fed to the input of the first delay element, the output of the first delay element is supplied to the input of the first multiplier 12 and the second delay element 15. The output of the second delay element 15 is supplied to the input of the second multiplier 13, the output signal of the first and second multiplier are supplied to the input of the adder 11, the output of it is supplied to the output terminal for outputting the output signal y.

The signal generating circuit output an oscillation signal with oscillation frequency of f=δ*(2πT) (where T is an oscillation period) by setting the multiplication coefficient A1 to 2 cos δ and A2 to −1, the initial value y1, y2 of each of the first and second delay element 14, 15 is set as satisfying the equation y1*A1+y2*A2=0, so the initial oscillation level goes necessarily to zero.

In addition, at the next clock timing immediately after the oscillation begins to start, the first delay element is set to zero level and the second delay element is set to y1, so the output signal level of y is equal to A2*y1. Therefore, the oscillation never halt unless the value of y1 is not equal to zero.

What is claimed is:

1. A signal generation circuit comprising;
an adder;
a first multiplier with a multiplication coefficient A1;
a second multiplier with a multiplication coefficient A2;
a first and second delay element; and
an initializing circuit;
wherein output signal from an output terminal is supplied to an input of the first delay element, the output signal of it is supplied to an input of the second delay element and an input of the first multiplier, an output signal of the second delay element is supplied to an input of the second multiplier, the output signal of the first and second multiplier are supplied to an input of the adder, the output signal of it is supplied to the output terminal;
wherein the initializing circuit which output initial value y1 and y2 of each of the first and second delay element at an power on stage such that an equation y1*A1+y2*A2=0 is satisfied.

2. The signal generation circuit of claim 1, wherein the multiplication coefficient A1 and A2 of each of the first and second multiplier is set to 2 cos δ and −1 so as to configure the signal generating circuit as an sign wave generating circuit with an oscillation frequency f=δ/(2πT), where T is an oscillation period.
